(19) United States
(12) Patent Application Publication
(10) Pub. No.: US 2025/0338583 A1
(43) Pub. Date: Oct. 30, 2025

(54) METHOD FOR CONTROLLING CARRIER CONCENTRATION OF NICKEL OXIDE AND SCHOTTKY DIODE MANUFACTURED BY THE METHOD

(71) Applicant: POWER CUBESEMI INC., Seongnam-si, Gyeonggi-do (KR)

(72) Inventors: Tai Young KANG, Gwangju-si (KR); Sin Su KYOUNG, Hanam-si (KR); Tae Jin NAM, Seongnam-si (KR); Yu Sup JUNG, Suwon-si (KR)

(73) Assignee: POWER CUBESEMI INC., Seongnam-si, Gyeonggi-do (KR)

(21) Appl. No.: 18/721,094

(22) PCT Filed: Dec. 16, 2022
(86) PCT No.: PCT/KR2022/020585

§ 371 Date: Mar. 17, 2025

(30) Foreign Application Priority Data
Dec. 16, 2021 (KR) 10-2021-0180500
Dec. 15, 2022 (KR) 10-2022-0175803

(51) Int. Cl. H10D 62/60; H01L 21/02; H10D 8/01; H10D 8/60; H10D 62/10; H10D 62/82

(52) U.S. Cl. CPC H10D 62/60; H01L 21/02631; H10D 8/051; H10D 8/053; H10D 8/60; H10D 62/105; H10D 62/124; H10D 62/8271

(57) ABSTRACT

A method for controlling the carrier concentration of nickel oxide is disclosed. The method for controlling the carrier concentration of nickel oxide comprises the steps of: preparing an n-type gallium oxide substrate on which an n-type gallium oxide epitaxial layer is formed; sputtering a nickel oxide target in a first mixed gas atmosphere of argon and oxygen, thereby depositing a first p-type nickel oxide layer on the n-type gallium oxide epitaxial layer, and sputtering the nickel oxide target in a second mixed gas atmosphere of argon and oxygen, thereby depositing a second p-type nickel oxide layer on the n-type gallium oxide epitaxial layer.

### FIELD OF INVENTION

The present invention relates to controlling the carrier concentration of nickel oxide.

### RELATED ART

Due to the rapid developments of the power, automotive electronics and home appliance industries, the demand for high-performance power semiconductor devices has exploded. Due to ongoing research, ultra-wideband semiconductors including silicon carbide and gallium nitride have achieved higher performance than silicon-based power semiconductors. However, they have the disadvantages of difficult bulk single crystal growth and high production costs.

Gallium oxide is an emerging ultra-wideband semiconductor material after silicon carbide and gallium nitride, with a bandgap of about 4.7 to about 4.9 eV, far beyond the bandgap width of silicon carbide and gallium nitride, and a theoretical breakdown field of 8 MV/cm. Gallium oxide is particularly capable of growing substrates and epitaxial layers at relatively low cost compared to other ultra-wideband semiconductor materials. However, because the effective hole mass of an appropriate p-type dopant is large and the acceptor activation energy is high, it is difficult to implement a pn homojunction-based β-Ga₂O₃ device.

### SUMMARY

According to one aspect of the present invention, there is provided a method of controlling carrier concentration of nickel oxide, including preparing an n-type gallium oxide substrate on which an n-type gallium oxide epitaxial layer is formed, depositing a first p nickel oxide layer on the n-type gallium oxide epitaxial layer by sputtering a nickel oxide target, in a first mixed gas atmosphere of argon and oxygen, and sputtering the nickel oxide target in a second mixed gas atmosphere of argon and oxygen to deposit a second p nickel oxide layer on the n-type gallium oxide epitaxial layer. An oxygen flow ratio of the first mixed gas and an oxygen flow ratio of the second mixed gas may be different, and the first p nickel oxide layer and the second p nickel oxide layer may have different carrier concentrations.

In one embodiment, the oxygen flow ratio is adjusted from 0.0% to 16.6%.

According to another aspect of the present invention, there is provided a method of manufacturing nickel oxide-gallium oxide heterojunction diode, including preparing an n-type gallium oxide substrate on which an n-type gallium oxide epitaxial layer is formed, forming a first mask defining a plurality of first p nickel oxide blocks in an active area on the n-type gallium oxide epitaxial layer, forming the plurality of first p nickel oxide blocks by sputtering a nickel oxide target in a first mixed gas atmosphere of argon and oxygen, forming a second mask defining a plurality of second p nickel oxide blocks in an edge area on the n-type gallium oxide epitaxial layer, forming the plurality of second p nickel oxide blocks by sputtering the nickel oxide target in a second mixed gas atmosphere of argon and oxygen, forming an insulating layer in the edge area, depositing a Schottky metal layer in the active area so as to contact an upper surface of the n-type gallium oxide epitaxial layer and the plurality of first p nickel oxide blocks, depositing a Schottky metal layer in the active area, and forming an anode electrode on the Schottky metal layer and a cathode electrode on a lower surface of the n-type gallium oxide substrate. An oxygen flow ratio of the first mixed gas and an oxygen flow ratio of the second mixed gas may be different, and the first p nickel oxide layer and the second p nickel oxide layer may have different carrier concentrations.

In one embodiment, the oxygen flow ratio is adjusted from 0.0% to 16.6%.

In one embodiment, the forming the plurality of first p nickel oxide blocks by sputtering a nickel oxide target in a first mixed gas atmosphere of argon and oxygen may include forming a plurality of first p+ nickel oxide blocks of which lower surfaces form a pn heterojunction with the upper surface of the n-type gallium oxide epitaxial layer in the active area, and a second p+ nickel oxide block of which lower surface forms the pn heterojunction with the upper surface of the n-type gallium oxide epitaxial layer at a boundary between the active area and the edge area to surround the active area, and removing the first mask.

In one embodiment, the second mask is formed to cover the entire active area and a portion of the second p+ nickel oxide block.

In one embodiment, the forming the plurality of second p nickel oxide blocks by sputtering the nickel oxide target in a second mixed gas atmosphere of argon and oxygen may include forming a plurality of first p− nickel oxide blocks of which lower surfaces form the pn heterojunction with the upper surface of the n-type gallium oxide epitaxial layer in the edge area, and a second p− nickel oxide block having an overlapping region on the second p+ nickel oxide block that is exposed by the second mask and an non-overlapping region of which lower surface forms the pn heterojunction with the upper surface of the n-type gallium oxide epitaxial layer in the edge area, and removing the second mask.

In one embodiment, the forming an insulating layer in the edge area may include forming the insulating layer to cover the entire edge region and a portion of the overlapping region.

According to still another aspect of the present invention, there is provided a nickel oxide-gallium oxide heterojunction diode, including an n-type gallium oxide substrate on which an n-type gallium oxide epitaxial layer is formed, a plurality of first p nickel oxide blocks formed in an active area and at a boundary between the active area and an edge area on the n-type gallium oxide epitaxial layer, a plurality of second p nickel oxide blocks formed in the edge area on the n-type gallium oxide epitaxial layer, an insulating layer formed in the edge area, a Schottky metal layer deposited in the active area to contact an upper surface of the n-type gallium oxide epitaxial layer and the plurality of first p nickel oxide blocks, and having a stepped upper surface in a direction toward the edge area, an anode electrode formed on the Schottky metal layer, and a cathode electrode formed on the back side of the n-type gallium oxide substrate. A portion of the second p nickel oxide block located at an innermost region of the edge area may be formed to overlap a portion of the first p nickel oxide block located at the boundary between the active area and the edge area.

In one embodiment, the plurality of first p nickel oxide blocks may be formed by sputtering a nickel oxide target in a first mixed gas atmosphere of argon and oxygen and the plurality of second p nickel oxide blocks may be formed by sputtering the nickel oxide target in a second mixed gas atmosphere of argon and oxygen. An oxygen flow ratio of the first mixed gas may be different from an oxygen flow ratio of the second mixed gas and a carrier concentration of the first p nickel oxide blocks may be different from a carrier concentration of the second p nickel oxide blocks.

In one embodiment, the oxygen flow ratio is adjusted from 0.0% to 16.6%.

In one embodiment, the plurality of first p nickel oxide blocks may include a plurality of first p+ nickel oxide blocks of which lower surfaces form a pn heterojunction with the upper surface of the n-type gallium oxide epitaxial layer in the active area, and a second p+ nickel oxide block of which lower surface forms the pn heterojunction with the upper surface of the n-type gallium oxide epitaxial layer at a boundary between the active area and the edge area to surround the active area.

In one embodiment, the plurality of second p nickel oxide blocks may include a plurality of first p− nickel oxide blocks of which lower surfaces form the pn heterojunction with the upper surface of the n-type gallium oxide epitaxial layer in the edge area, and a second p− nickel oxide block having an overlapping region on the second p+ nickel oxide block and an non-overlapping region of which lower surface forms the pn heterojunction with the upper surface of the n-type gallium oxide epitaxial layer in the edge area.

In one embodiment, the insulating layer may extend laterally to cover a portion of the second p nickel oxide block overlapping with a portion of the first p nickel oxide block.

In one embodiment, the Schottky metal layer extends laterally to cover a portion of the insulating layer.

### BRIEF DESCRIPTION OF DRAWINGS

Hereinafter, embodiments of the invention will be described with reference to the accompanying drawings. For the purpose of easy understanding of the invention, the same elements will be referred to by the same reference signs. Configurations illustrated in the drawings are examples for describing the invention, and do not restrict the scope of the invention. Particularly, in the drawings, some elements are slightly exaggerated for the purpose of easy understanding of the invention. Since the drawings are used to easily understand the invention, it should be noted that widths, depths, and the like of elements illustrated in the drawings might change at the time of actual implementation thereof. Meanwhile, throughout the detailed description of the invention, the same components are described with reference to the same reference numerals.

FIG. 1 exemplarily illustrates a pn heterojunction diode and a Schottky diode used to measure carrier concentrations of p-type nickel oxide;

FIG. 2 is a graph showing the measured carrier concentration of p-type nickel oxide manufactured by controlling the oxygen flow ratio;

FIG. 3 is a graph showing the current density measured by applying a reverse voltage to a pn heterojunction diode manufactured by controlling the oxygen flow ratio;

FIG. 4 is a graph showing the current density measured by applying a forward voltage to a pn heterojunction diode manufactured by controlling the oxygen flow ratio;

FIG. 5 is a graph showing the turn-on voltage of a pn heterojunction diode manufactured by controlling the oxygen flow ratio;

FIG. 6 is a graph showing the capacitance measurements of a pn heterojunction diode manufactured by controlling the oxygen flow ratio;

FIG. 7 exemplarily illustrates a nickel oxide-gallium oxide pn heterojunction Schottky diode; and

FIG. 8 and FIG. 9 exemplarily illustrate the process of manufacturing the nickel oxide-gallium oxide pn heterojunction Schottky diode of FIG. 7.

### DETAILED DESCRIPTION

Embodiments which will be described below with reference to the accompanying drawings can be implemented singly or in combination with other embodiments. But this is not intended to limit the present invention to a certain embodiment, and it should be understood that all changes, modifications, equivalents or replacements within the spirits and scope of the present invention are included. Especially, any of functions, features, and/or embodiments can be implemented independently or jointly with other embodiments. Accordingly, it should be noted that the scope of the invention is not limited to the embodiments illustrated in the accompanying drawings.

Terms such as first, second, etc., may be used to refer to various elements, but, these element should not be limited due to these terms. These terms will be used to distinguish one element from another element.

The terms used in the following description are intended to merely describe specific embodiments, but not intended to limit the invention. An expression of the singular number includes an expression of the plural number, so long as it is clearly read differently. The terms such as “include” and “have” are intended to indicate that features, numbers, steps, operations, elements, components, or combinations thereof used in the following description exist and it should thus be understood that the possibility of existence or addition of one or more other different features, numbers, steps, operations, elements, components, or combinations thereof is not excluded.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings.

Hereinafter, embodiments of the present invention will be described in detail with reference to the accompanying drawings.

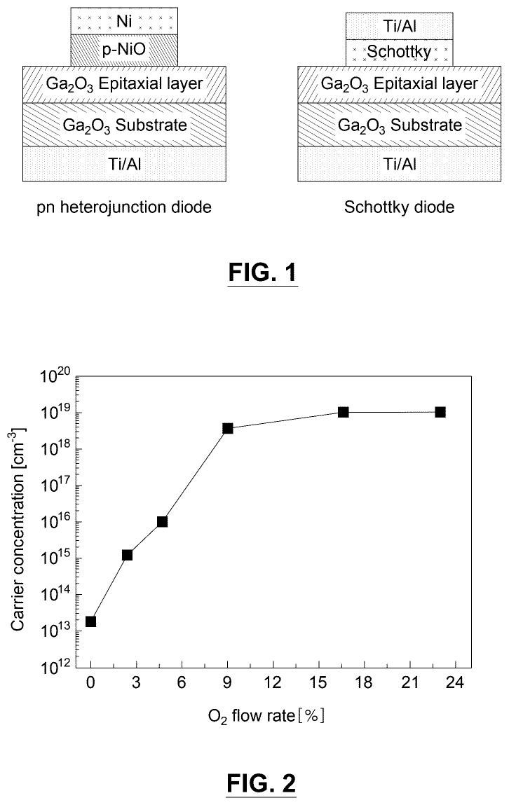

FIG. 1 exemplarily illustrates a pn heterojunction diode and a Schottky diode used to measure carrier concentrations of p-type nickel oxide.

The pn heterojunction diode includes an n-type gallium oxide substrate, an n-type gallium oxide epitaxial layer formed on the main surface of the n-type gallium oxide substrate, a p-type nickel oxide layer formed on the n-type gallium oxide epitaxial layer, and an anode electrode formed on the p-type nickel oxide layer, and a cathode electrode formed on the lower surface of the n-type gallium oxide substrate. The Schottky diode includes an n-type gallium oxide substrate, an n-type gallium oxide epitaxial layer formed on the main surface of the n-type gallium oxide substrate, a Schottky metal layer formed on the n-type gallium oxide epitaxial layer, an anode formed on the Schottky metal layer, and a cathode electrode formed on the lower surface of the n-type gallium oxide substrate.

The anode electrode of the pn heterojunction diode is made of nickel and in ohmic contact with the p-type nickel oxide layer. When manufacturing the pn heterojunction diode, the p-type nickel oxide layer and the anode electrode are formed in-situ. After forming a photoresist mask defining a junction region on the n-type gallium oxide epitaxial layer, in a mixed gas atmosphere of argon and oxygen, the p-type nickel oxide layer is formed to a thickness of about 300 nm on the photoresist mask and the exposed n-type gallium oxide epitaxial layer by RF magnetron sputtering of a nickel oxide target. During sputtering, an oxygen flow ratio may be adjusted between about 0.0% and about 23.0%, a chamber pressure may be maintained at about 5 mTorr, and a power of about 150 W can be applied for about 90 minutes.

The anode electrode of the pn heterojunction diode and the Schottky metal layer of the Schottky diode are deposited to a thickness of about 100 nm on the n-type gallium oxide epitaxial layer in the junction region by sputtering a nickel target in an argon atmosphere. During sputtering, a flow of argon may be maintained at about 20 sccm, the chamber pressure may be maintained at about 5 mTorr, and a power of about 100 W may be applied for about 8 minutes.

FIG. 2 is a graph showing the measured carrier concentration of p-type nickel oxide manufactured by controlling the oxygen flow ratio.

The hole concentration of the p-type nickel oxide layer 120′ can be adjusted depending on the oxygen flow during deposition. FIG. 2 shows the hole concentration of the p-type nickel oxide layer deposited while adjusting the oxygen flow ratio to about 0.0%, about 2.4%, about 4.7%, about 9.0%, about 16.6%, and about 23.0% in argon-oxygen mixed gas, and Table 1 shows the process parameters for each oxygen flow ratio.

TABLE 1

| | Oxygen flow ratio | | | | | |
|---|---|---|---|---|---|---|
| | 0.0% | 2.4% | 4.7% | 9.0% | 16.6% | 23.0% |
| Process | 37 | 66 | 85 | 89 | 90 | 92 |
| time(Min.) | | | | | | |
| Deposition | 8.1 | 4.5 | 3.5 | 3.4 | 3.3 | 3.2 |
| rate(nm/min) | | | | | | |
| Hole | 1.8 × 10¹³ | 1.2 × 10¹⁵ | 1.0 × 10¹⁶ | 3.7 × 10¹⁸ | 1.05 × 10¹⁹ | 1.03 × 10¹⁹ |
| concentration | | | | | | |
| (cm⁻³) | | | | | | |

Referring to FIG. 2, as the oxygen flow ratio increases, the hole concentration increases. The hole concentration in the oxygen flow ratio range of about 9.0% to about 23.0% increases significantly compared to the hole concentration in the oxygen flow ratio range of about 0.0% to about 4.7%. Accordingly, the oxygen flow ratio can be adjusted in the range of about 0.0% to about 16.6% to implement the carrier concentration required by design.

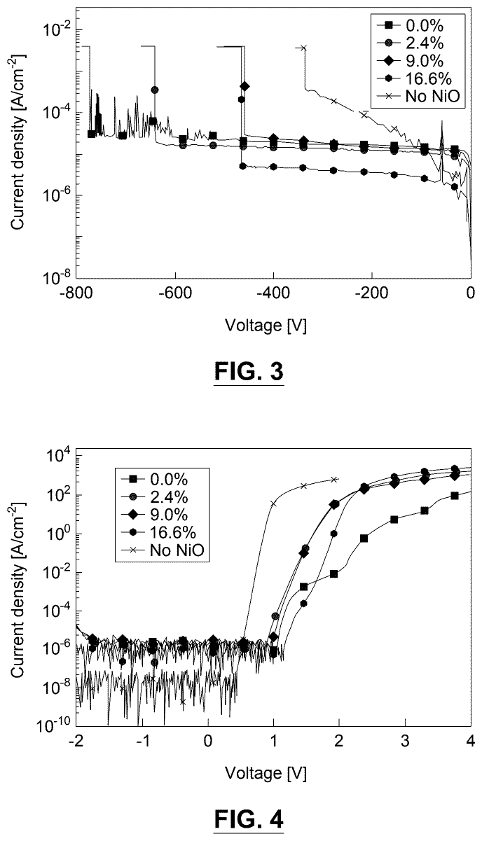

FIG. 3 is a graph showing the current density measured by applying a reverse voltage to a pn heterojunction diode manufactured by controlling the oxygen flow ratio.

Referring to FIG. 3, it can be seen that as the oxygen flow ratio increases, the breakdown voltage and the leakage current decrease when the reverse voltage is applied. The breakdown voltage of the pn heterojunction diode manufactured with an oxygen flow ratio of about 16.6% is about −465V, which is not much different from the breakdown voltage of about −461V of the pn heterojunction diode manufactured with an oxygen flow ratio of about 9.0%. On the other hand, the breakdown voltage of a pn heterojunction diode manufactured with an oxygen flow ratio of about 2.4% is about −641V, and the breakdown voltage of a pn heterojunction diode manufactured with an oxygen flow ratio of about 0.0% is about −772V. The No NiO curve is the reverse voltage characteristic of the Schottky diode.

FIG. 4 is a graph showing the current density measured by applying a forward voltage to a pn heterojunction diode manufactured by controlling the oxygen flow ratio.

Referring to FIG. 4, it can be seen that as the oxygen flow ratio increases, the current density increases when forward voltage is applied, and the contact resistance with the ohmic contact metal layer, that is, the anode electrode, decreases. For a pn heterojunction diode manufactured with an oxygen flow ratio of about 2.4% to about 16.6%, the forward current density exhibits the typical shape of a diode voltage-current density curve, whereas the voltage-current density curve of a pn heterojunction diode manufactured with an oxygen flow ratio of about 0.0% exhibits a hump. This is because a large contact resistance occurred between the ohmic contact metal layer and the p-type gallium oxide layer due to the low hole concentration. The No NiO curve is the forward voltage characteristic of a Schottky diode.

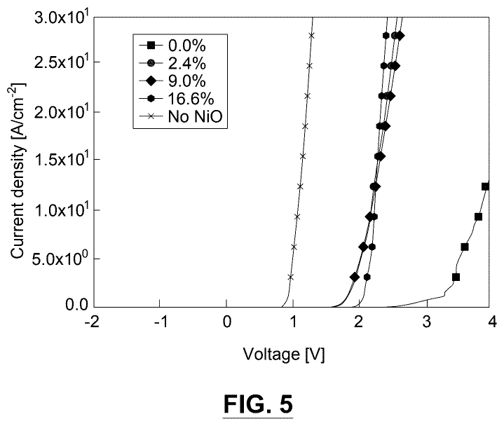

FIG. 5 is a graph showing the turn-on voltage of a pn heterojunction diode manufactured by controlling the oxygen flow ratio.

Referring to FIG. 5, it can be seen that as the oxygen flow ratio increases, the turn-on voltage increases. The turn-on voltage of the Schottky diode is about 1.0V, the turn-on voltage of the pn heterojunction diode manufactured with an oxygen flow ratio of about 9.0% is about 2.0V, and the turn-on voltage of the pn heterojunction diode manufactured with an oxygen flow ratio of about 16.6% is about It is 2.2V. The No NiO curve represents the turn-on voltage of the Schottky diode.

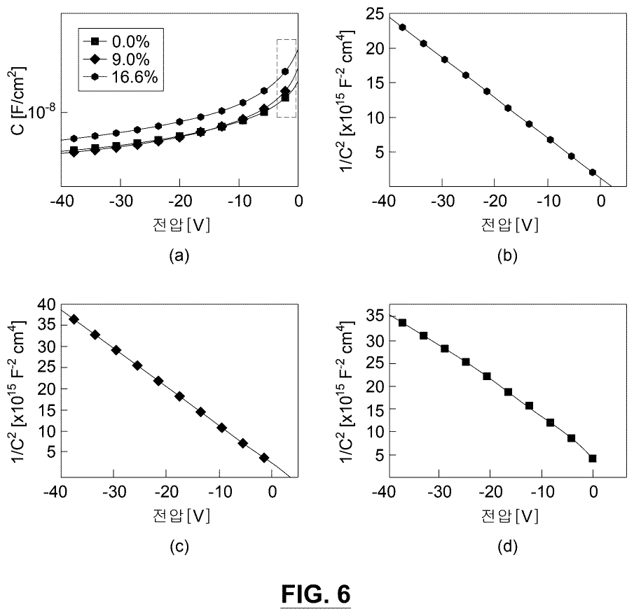

FIG. 6 is a graph showing the capacitance measurements of a pn heterojunction diode manufactured by controlling the oxygen flow ratio.

Referring to FIG. 6, the voltage-capacitance relationship according to the change in oxygen flow ratio can be seen. The voltage V-capacitance C curve shows the size of the depletion region at 0V. At 0V, the larger the capacitance value, the smaller the size of the depletion region. Therefore, it can be seen that the depletion region of the nickel oxide-gallium oxide pn heterojunction Schottky diode manufactured with an oxygen flow ratio of about 0.0% is the largest.

Meanwhile, the x-axis intercept of the V-1/C² curve represents the built-in voltage V_{BI} of the diode. It can be seen that as the oxygen flow ratio increases, V_{BI} decreases. The V_{BI} of the pn heterojunction diode manufactured with an oxygen flow ratio of about 16.6% is about 2.2V, and the V_{BI} of the pn heterojunction diode manufactured with an oxygen flow ratio of about 9.0% is about 2.35V. The V_{BI} of the pn heterojunction diode manufactured with an oxygen flow ratio of about 0.0% could not be measured.

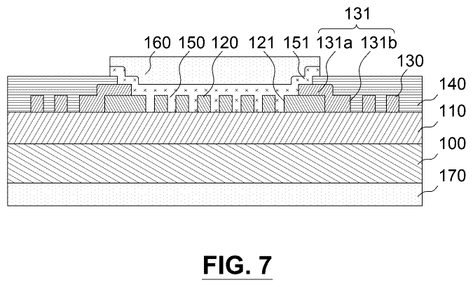

FIG. 7 exemplarily illustrates a nickel oxide-gallium oxide pn heterojunction Schottky diode.

Referring to FIG. 7, the nickel oxide-gallium oxide pn heterojunction Schottky diode may include an n-type gallium oxide substrate 100, an n-type gallium oxide epitaxial layer 110, p+ nickel oxide blocks 120, 121, and p− nickel oxide blocks 130, 131, an insulating layer 140, a Schottky metal layer 150, an anode electrode 160, and a cathode electrode 170.

The n-type gallium oxide substrate 100 may be formed of single crystal β-gallium oxide (β-Ga₂O₃) doped with an n-type dopant. The thickness of the n-type gallium oxide substrate 100 may be about 590 μm, and the n-type dopant concentration may be about 4E18 cm⁻³. The n-type dopant may be, for example, tin (Sn) or silicon (Si).

The n-type gallium oxide epitaxial layer 110 may be undoped or n-type doped β-gallium oxide epitaxially grown on the main surface of the n-type gallium oxide substrate 100. The n-type dopant may be, for example, silicon (Si), and the concentration of the n-type dopant may be about 1E16 cm⁻³. The thickness of the n-type gallium oxide epitaxial layer 110 may be about 10 μm.

The p-type nickel oxide (NiOₓ) region may include p+ nickel oxide blocks 120, 121 and p− nickel oxide blocks 130, 131. The p-type nickel oxide blocks are formed on the upper surface of the n-type gallium oxide epitaxial layer 110, forming a pn heterojunction with the n-type gallium oxide epitaxial layer 110. A plurality of first p+ nickel oxide blocks 120 are formed in the active area of the Schottky diode, and a second p+ nickel oxide block 121 is formed at the boundary between the active area and the edge area to partially or completely surround the active area, thereby defining the active area. A plurality of first p− nickel oxide blocks 130 are formed in the edge area, and a second p− nickel oxide block 131 is formed on the innermost region of the edge area to partially overlap with the second p+ nickel oxide block 121. In detail, the second p− nickel oxide block 131 includes an overlapping region 131a formed on the upper surface of the second p+ nickel oxide block 121 and a non-overlapping region 131b formed on the upper surface of the n-type gallium oxide epitaxial layer 110. The overlapping region 131a of the second p− nickel oxide block 131 does not extend beyond the second p+ nickel oxide block 121 to the active area in the direction from the edge area to the active area.

The plurality of the first p+ nickel oxide blocks 120 serve as a junction barrier, and the second p+ nickel oxide block 121 serves as a buffer. Meanwhile, the plurality of the first p − nickel oxide blocks 130 serve as the electric field limiting structure, for example, guard rings, and the second p− nickel oxide block 131 serves to disperse the electric field in conjunction with the second p+ nickel oxide block 121. The p+ nickel oxide blocks 120, 121 and the p− nickel oxide blocks 130, 131 may have different carrier concentrations by adjusting the oxygen flow ratio.

The insulating layer 140 is formed on at least a portion of the second p− nickel oxide block 131 and on top of the edge area. The insulating layer 140 fills the space formed between the plurality of the first p− nickel oxide blocks 130. Therefore, at least a portion of the lower surface of the insulating layer 140 is in contact with the first p− nickel oxide blocks 130 and the second p− nickel oxide block 131, and the remaining area is in contact with the upper surface of the n-type gallium oxide epitaxial layer 110. The insulating layer 140 extends to the overlapping region 131a of the second p+ nickel oxide block 131 in contact with the second p− nickel oxide block 121 in the direction from the edge area to the active area, but does not extend beyond the overlapping region 131a of the second p− nickel oxide block 131 to the second p+ nickel oxide block 121.

The Schottky metal layer 150 is formed on the upper surface of the n-type gallium oxide epitaxial layer 110 in the active area so as to contact the upper surface of the n-type gallium oxide epitaxial layer 110 and the plurality of the first p+ nickel oxide blocks 120. The Schottky metal layer 150 and the upper surface of the n-type gallium oxide epitaxial layer 110 is in Schottky contact, and the Schottky metal layer 150 and the plurality of the first p+ nickel oxide blocks 120 are in ohmic contact. In the active area, the Schottky metal layer 140 may extend in the horizontal direction.

Meanwhile, at the boundary between the active area and the edge area, the Schottky metal layer 150 is formed in a stepped structure. At the boundary between the active area and the edge area, the entire lower surface of the second p+ nickel oxide block 121 is in contact with the upper surface of the n-type gallium oxide epitaxial layer 110, a lower surface of a portion of the second p− nickel oxide block 131, that is, the non-overlapping region 131b of the second p− nickel oxide block 131 is in contact with the upper surface of the n-type gallium oxide epitaxial layer 110 in the edge area, a lower surface of the remainder of the second p− nickel oxide block 131, that is, the overlapping region 131a of the second p− nickel oxide block 131 is in contact with a portion of the upper surface of the second p+ nickel oxide block 121, and a portion of the lower surface of the insulating layer 140 is in contact with a portion of the upper surface of the overlapping region 131a of the second p− nickel oxide block 131. Because of this, the Schottky metal layer 150 has a stepped upper surface that rises as it approaches the edge area. The Schottky metal layer 150 may extend to contact a portion of the upper surface of the insulating layer 140 and serve as a field plate.

The anode electrode 160 is formed on the upper surface of the Schottky metal layer 140, and the cathode electrode 170 is formed on the lower surface of the n-type gallium oxide substrate 100. A silicide layer (not shown) for ohmic contact may be formed between the n-type gallium oxide substrate 100 and the cathode electrode 170.

The operation of the diode having a plurality of first p+ nickel oxide blocks 120 will be described.

The plurality of the first p+ nickel oxide blocks 120 form a pn heterojunction with the n-type gallium oxide epitaxial layer 110, and the breakdown voltage and leakage current characteristics can be improved compared to a conventional Schottky diode. When a reverse voltage is applied, the plurality of the first p+ nickel oxide blocks 120 form a depletion layer due to pn junction with the n-type gallium oxide epitaxial layer 110. Since the depletion layer formed along the lower surface of the plurality of the first p+ nickel oxide blocks 120 blocks the path through which leakage current can flow, it has a lower leakage current value than a typical Schottky diode. In particular, the depletion layer formed along the lower surface of the plurality of the first p+ nickel oxide blocks 120 can relatively reduce the electric field concentrated in the area where the Schottky metal layer 150 and the n-type gallium oxide epitaxial layer 110 are in contact. Because of this, it is possible to implement a relatively higher threshold voltage than a typical Schottky diode.

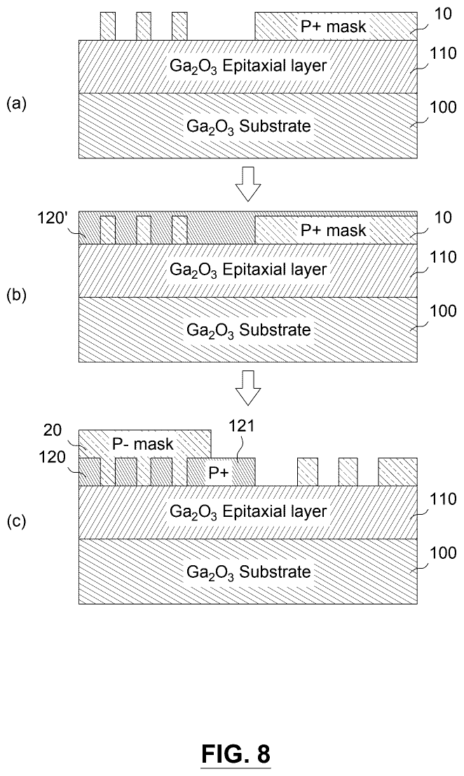

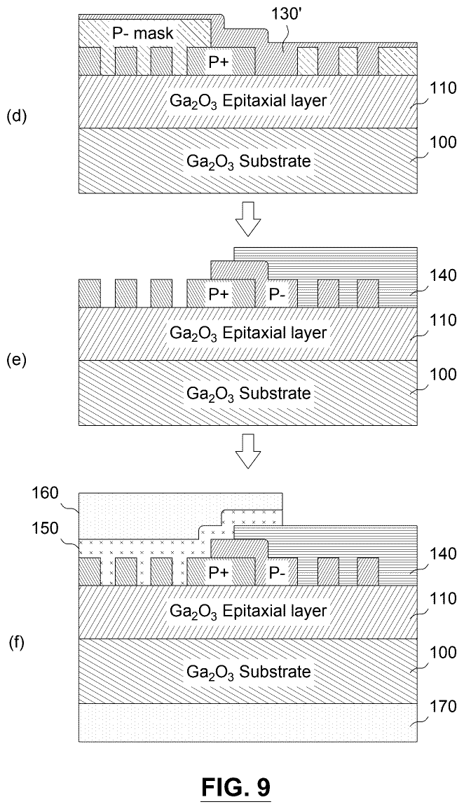

FIG. 8 and FIG. 9 exemplarily illustrate the process of manufacturing the nickel oxide-gallium oxide pn heterojunction Schottky diode of FIG. 7.

In (a), the n-type gallium oxide epitaxial layer 110 is formed on the main surface of the n-type gallium oxide substrate 100, and a P+ mask 10 is formed on the upper surface of the n-type gallium oxide epitaxial layer 110.

The n-type gallium oxide substrate 100 is cleaned and plasma treated to remove foreign substances. The n-type gallium oxide epitaxial layer 110 may be undoped or n-type doped β-gallium oxide epitaxially grown on the main surface of the n-type gallium oxide substrate 100. The n-type dopant may be, for example, silicon (Si), and the concentration of the n-type dopant may be about 1E16 cm⁻³. The thickness of the n-type gallium oxide epitaxial layer 110 may be about 10 μm. The n-type gallium oxide epitaxial layer 110 may be deposited on the n-type gallium oxide substrate 100 by, for example, halide vapor phase epitaxy (HVPE), metalorganic chemical vapor deposition (MOCVD), Mist CVD, molecular beam epitaxy (MBE), pulsed laser deposition (PLD), and so on.

The p+ mask 10 can be formed by spin-coating photoresist on the n-type gallium oxide epitaxial layer 110 to a thickness of about 1.6 μm and then going through photo, development, and etching processes. The p+ mask 10 defines the first and the second p+ nickel oxide blocks 120, 121.

In (b), a p+ nickel oxide layer 120′ is formed in the first and the second p+ nickel oxide blocks 120, 121 defined by the p+ mask 10. In a mixed gas atmosphere of argon and oxygen, the p+ nickel oxide layer 120′ is deposited by sputtering a nickel oxide target or a nickel target. During sputtering, the oxygen flow ratio may be adjusted between about 9.0% and about 16.6%, the chamber pressure may be maintained at about 5 mTorr, and a power of about 150 W may be applied for about 90 minutes.

After sputtering, the p+ mask 10 is etched or lifted off to form the first and the second p+ nickel oxide blocks 120, 121.

In (c), a p− mask 20 is formed on the upper surface of the n-type gallium oxide epitaxial layer 110. The p− mask 20 is formed in the same way as the p+ mask 10. The p− mask 20 is formed on the entire active area, the plurality of the first p+ nickel oxide blocks 120 and a portion of the second p+ nickel oxide block 121. The p− mask 20 is also formed on the upper surface of the n-type gallium oxide epitaxial layer 110 in the edge area.

In (d), a p− nickel oxide layer 130′ is formed on the p− mask 20 and in the first and second p− nickel oxide blocks 130, 131 defined by the p− mask 20. In the mixed gas atmosphere of argon and oxygen, the p− nickel oxide layer 130′ is deposited by sputtering a nickel oxide target. During sputtering, the oxygen flow ratio may be adjusted between about 0.0% and about 9.0%, the chamber pressure may be maintained at about 5 mTorr, and a power of about 150 W may be applied for about 90 minutes.

After sputtering, the p− mask 20 is etched or lifted off to form the first and second p− nickel oxide blocks 130, 131.

In (e), the insulating layer 140 is formed in the edge area of the n-type gallium oxide epitaxial layer 110. The insulating layer 140 extends to the overlapping region 131a of the second p− nickel oxide block 131 that is in contact with the second p+ nickel oxide block 121 in the direction from the edge area to the active area, but does not extend beyond the overlapping region 131a of the second p− nickel oxide block 131 to the second p+ nickel oxide block 121. The insulating layer 140 may be formed by depositing, for example, silicon oxide (SiO₂), phosphosilicate glass (PSG), borosilicate glass (BSG), or borophosphosilicate glass (BPSG).

In (f), the Schottky metal layer 150 is formed on the n-type gallium oxide epitaxial layer 110, the first p+ nickel oxide blocks 120 and the second p+ nickel oxide block 121 not overlapped with the second p− nickel oxide block 131 in the active area, and on the second p− nickel oxide block 131 not overlapped with the insulating layer 140 and the insulating layer 140 in the edge region. In the argon atmosphere, the Schottky metal layer 150 is deposited to a thickness of about 100 nm by sputtering a nickel target. During sputtering, the argon flow may be maintained at about 20 sccm, the chamber pressure may be maintained at about 5 mTorr, and a power of about 100 W may be applied for about 8 minutes.

Next, the anode electrode 160 is formed on the Schottky metal layer 150, and the cathode electrode 170 is formed on the lower surface of the n-type gallium oxide substrate 100. The anode electrode 160 and the cathode electrode 170 are formed of metal such as Ti, Au, Al or metal alloy.

The above description of the invention is exemplary, and those skilled in the art can understand that the invention can be modified in other forms without changing the technical concept or the essential feature of the invention. Therefore, it should be understood that the above-mentioned embodiments are exemplary in all respects, but are not definitive.

The scope of the invention is defined by the appended claims, not by the above detailed description, and it should be construed that all changes or modifications derived from the meanings and scope of the claims and equivalent concepts thereof are included in the scope of the invention.

What is claimed is:

1. A method of controlling carrier concentration of nickel oxide, comprising:
preparing an n-type gallium oxide substrate on which an n-type gallium oxide epitaxial layer is formed;
depositing a first p nickel oxide layer on the n-type gallium oxide epitaxial layer by sputtering a nickel oxide target, in a first mixed gas atmosphere of argon and oxygen; and
sputtering the nickel oxide target in a second mixed gas atmosphere of argon and oxygen to deposit a second p nickel oxide layer on the n-type gallium oxide epitaxial layer,
wherein an oxygen flow ratio of the first mixed gas and an oxygen flow ratio of the second mixed gas are different,
wherein the first p nickel oxide layer and the second p nickel oxide layer have different carrier concentrations.

2. The method of claim 1, wherein the oxygen flow ratio is adjusted from 0.0% to 16.6%.

3. A method of manufacturing nickel oxide-gallium oxide heterojunction diode, comprising:
preparing an n-type gallium oxide substrate on which an n-type gallium oxide epitaxial layer is formed;
forming a first mask defining a plurality of first p nickel oxide blocks in an active area on the n-type gallium oxide epitaxial layer;
forming the plurality of first p nickel oxide blocks by sputtering a nickel oxide target in a first mixed gas atmosphere of argon and oxygen;
forming a second mask defining a plurality of second p nickel oxide blocks in an edge area on the n-type gallium oxide epitaxial layer;
forming the plurality of second p nickel oxide blocks by sputtering the nickel oxide target in a second mixed gas atmosphere of argon and oxygen;
forming an insulating layer in the edge area;
depositing a Schottky metal layer in the active area so as to contact an upper surface of the n-type gallium oxide epitaxial layer and the plurality of first p nickel oxide blocks;
depositing a Schottky metal layer in the active area; and
forming an anode electrode on the Schottky metal layer and a cathode electrode on a lower surface of the n-type gallium oxide substrate,
wherein an oxygen flow ratio of the first mixed gas and an oxygen flow ratio of the second mixed gas are different,
wherein the first p nickel oxide layer and the second p nickel oxide layer have different carrier concentrations.

4. The method of claim 3, wherein the oxygen flow ratio is adjusted from 0.0% to 16.6%.

5. The method of claim 3, wherein the forming the plurality of first p nickel oxide blocks by sputtering a nickel oxide target in a first mixed gas atmosphere of argon and oxygen comprises:
forming a plurality of first p+ nickel oxide blocks of which lower surfaces form a pn heterojunction with the upper surface of the n-type gallium oxide epitaxial layer in the active area, and a second p+ nickel oxide block of which lower surface forms the pn heterojunction with the upper surface of the n-type gallium oxide epitaxial layer at a boundary between the active area and the edge area to surround the active area; and
removing the first mask.

6. The method of claim 5, wherein the second mask is formed to cover the entire active area and a portion of the second p+ nickel oxide block.

7. The method of claim 6, wherein the forming the plurality of second p nickel oxide blocks by sputtering the nickel oxide target in a second mixed gas atmosphere of argon and oxygen comprises:
forming a plurality of first p− nickel oxide blocks of which lower surfaces form the pn heterojunction with the upper surface of the n-type gallium oxide epitaxial layer in the edge area, and a second p− nickel oxide block having an overlapping region on the second p+ nickel oxide block that is exposed by the second mask and an non-overlapping region of which lower surface forms the pn heterojunction with the upper surface of the n-type gallium oxide epitaxial layer in the edge area; and
removing the second mask.

8. The method of claim 7, wherein the forming an insulating layer in the edge area comprises forming the insulating layer to cover the entire edge region and a portion of the overlapping region.

9. A nickel oxide-gallium oxide heterojunction diode, comprising:
an n-type gallium oxide substrate on which an n-type gallium oxide epitaxial layer is formed;
a plurality of first p nickel oxide blocks formed in an active area and at a boundary between the active area and an edge area on the n-type gallium oxide epitaxial layer;
a plurality of second p nickel oxide blocks formed in the edge area on the n-type gallium oxide epitaxial layer;
an insulating layer formed in the edge area;
a Schottky metal layer deposited in the active area to contact an upper surface of the n-type gallium oxide epitaxial layer and the plurality of first p nickel oxide blocks, and having a stepped upper surface in a direction toward the edge area;
an anode electrode formed on the Schottky metal layer; and
a cathode electrode formed on the back side of the n-type gallium oxide substrate,
wherein a portion of the second p nickel oxide block located at an innermost region of the edge area is formed to overlap a portion of the first p nickel oxide block located at the boundary between the active area and the edge area.

10. The nickel oxide-gallium oxide heterojunction diode of claim 9, wherein the plurality of first p nickel oxide blocks are formed by sputtering a nickel oxide target in a first mixed gas atmosphere of argon and oxygen and the plurality of second p nickel oxide blocks are formed by sputtering the nickel oxide target in a second mixed gas atmosphere of argon and oxygen,
wherein an oxygen flow ratio of the first mixed gas is different from an oxygen flow ratio of the second mixed gas and a carrier concentration of the first p nickel oxide blocks is different from a carrier concentration of the second p nickel oxide blocks.

11. The nickel oxide-gallium oxide heterojunction diode of claim 10, wherein the oxygen flow ratio is adjusted from 0.0% to 16.6%.

12. The nickel oxide-gallium oxide heterojunction diode of claim 9, wherein the plurality of first p nickel oxide blocks comprises:
a plurality of first p+ nickel oxide blocks of which lower surfaces form a pn heterojunction with the upper surface of the n-type gallium oxide epitaxial layer in the active area; and
a second p+ nickel oxide block of which lower surface forms the pn heterojunction with the upper surface of the n-type gallium oxide epitaxial layer at a boundary between the active area and the edge area to surround the active area.

13. The nickel oxide-gallium oxide heterojunction diode of claim 12, wherein the plurality of second p nickel oxide blocks comprises:
a plurality of first p− nickel oxide blocks of which lower surfaces form the pn heterojunction with the upper surface of the n-type gallium oxide epitaxial layer in the edge area; and
a second p− nickel oxide block having an overlapping region on the second p+ nickel oxide block and an non-overlapping region of which lower surface forms the pn heterojunction with the upper surface of the n-type gallium oxide epitaxial layer in the edge area.

14. The nickel oxide-gallium oxide heterojunction diode of claim 9, wherein the insulating layer extends laterally to cover a portion of the second p nickel oxide block overlapping with a portion of the first p nickel oxide block.

15. The nickel oxide-gallium oxide heterojunction diode of claim 14, wherein the Schottky metal layer extends laterally to cover a portion of the insulating layer.
